(19) United States
(12) Patent Application Publication
(10) Pub. No.: US 2012/0225245 A1
(43) Pub. Date: Sep. 6, 2012

(54) SPACER FORMING METHOD, METHOD OF MANUFACTURING DISPLAY PANEL SUBSTRATE, SPACER, AND DISPLAY PANEL SUBSTRATE

(75) Inventor: Yoshio Dejima, Osaka (JP)

(73) Assignee: SHARP KABUSHIKI KAISHA, Osaka (JP)

(21) Appl. No.: 13/505,597

(22) PCT Filed: Sep. 15, 2010
(86) PCT No.: PCT/JP2010/065905

§ 371 Date: May 2, 2012

(30) Foreign Application Priority Data
Nov. 6, 2009 (JP) 2009-255538

(51) Int. Cl. B32B 3/10; G03F 7/20

(52) U.S. Cl. 428/138; 430/320

(57) ABSTRACT

Disclosed is a display panel substrate including a spacer that allows adjustment of the height of the spacer without affecting color characteristics of colored patterns. The display panel substrate comprises colored patterns 13r, 13g, and 13b of a prescribed plurality of colors for use in a color display, the colored patterns 13r, 13g, and 13b being made of photosensitive materials; and a spacer 2 having a first subspacer 21, an opening formed in the central portion of the plane direction thereof, and a second subspacer 22, a portion therereof overlaping upon the first subspacer and another portion thereof being fitted upon the opening that is formed on the first subspacer, wherein the first subspacer 21 is formed of the same material as that of one color of the colored patterns 13r, 13g, 13b among the plurality of colored patterns 13r, 13g, and 13b, and the second subspacer 22 is formed of the same material as that of a color of the colored patterns 13r, 13g, and 13b different from that of the first subspacer 21.

### TECHNICAL FIELD

The present invention relates to a method for forming a spacer, a method for manufacturing a display panel substrate, a spacer, and a display panel substrate. Specifically, the present invention relates to a method for forming a spacer that defines a gap (i.e., cell gap) between two display panel substrates, a method for manufacturing a display panel substrate equipped with such a spacer, a spacer that defines the cell gap, and a display panel substrate equipped with such a spacer.

### BACKGROUND ART

A liquid crystal display panel is generally equipped with two display panel substrates. An active matrix type liquid crystal display panel, for example, is generally equipped with a TFT array substrate and a color filter as display panel substrates. The two display panel substrates are bonded together so as to face each other with a prescribed small gap therebetween, and this gap is filled by a liquid crystal (a layer of liquid crystal is formed between the two display panel substrates).

The gap between the two display panel substrates (referred to hereinafter as a “cell gap”) affects the display characteristics of the liquid crystal display panel (the operating characteristics of the liquid crystal, in particular). Thus, the cell gap must be maintained at a prescribed value. Therefore, generally, a configuration where a spacer is interposed between the two display panel substrates or a configuration where a spacer is formed in one of the two display panel substrates is used.

A configuration where the spacer is formed in the color filter by using the same material as that of the colored pattern may be employed, for example. Specifically, simultaneously with formation of each color of the colored pattern, a protruding structure is formed of the same material as that of the colored pattern at a prescribed position of the surface of the display panel substrate. This protruding structure becomes the spacer.

However, a configuration where the spacer is formed of the same material as that of the colored pattern in the same step as the step of forming the colored pattern poses the following problems: because the thickness of the colored pattern of each color affects the display characteristics (particularly the color characteristics) of the liquid crystal display panel, the colored pattern of each color needs to be formed at a prescribed thickness. However, with this configuration, in order to change the height of the spacer so as to adjust the cell gap, the thickness of the colored pattern needs to be changed, which causes the display characteristics of the liquid crystal display panel to change. Thus, it is difficult to change the height of the spacer without affecting the display characteristics of the liquid crystal display panel.

Moreover, the height and shape of the spacer must be made uniform so as to maintain uniformity of the display panel cell gap over the entire surface. However, it has been becoming more difficult to make the height and shape of the spacer uniform over the entire surface of the display panel. That is, when the spacer is formed of a photosensitive material, the height and shape of the spacer vary in accordance with the heating temperature during heat treatment or the like. Thus, in order to maintain uniform height and shape of the spacer, it is necessary to perform the heat treatment such that a uniform temperature is maintained over the entire surface of a mother substrate during heat treatment. However, as the surface area of the mother substrate becomes larger, it has been more and more difficult to heat the entire surface of the mother substrate to a uniform temperature.

Because the spacer is formed of the photosensitive material, after the heat treatment, the end portion thereof has a spherical shape or a protruding rounded face. When the end portion of the spacer has a spherical shape or a protruding rounded face, the tip of the spacer becomes likely to be pressed down in bonding the two display panel substrates together. When the tip of the spacer is pressed down, it becomes difficult to maintain a prescribed cell gap due to the decrease in height of the spacer. Moreover, when the spacers have non-uniform shapes as described above, the manner in which spacers are pressed down becomes uneven. As a result, it becomes difficult to maintain a uniform cell gap.

### RELATED ART DOCUMENTS

### Patent Documents

Patent Document 1: Japanese Patent Application Laid-Open Publication No. 2006-23733

### SUMMARY OF THE INVENTION

### Problems to be Solved by the Invention

In consideration of the aforementioned circumstances, the present invention is aiming at: providing a spacer capable of adjusting the cell gap with ease, a display panel substrate and a liquid crystal panel equipped with this spacer, and a method for forming this spacer; providing a spacer capable of adjusting the cell gap without increasing the number of process steps, a display panel substrate and a liquid crystal panel equipped with this spacer, and a method for forming this spacer; and to provide a spacer capable of adjusting the cell gap without affecting (or being affected by) the thickness of the color filter layer, a display panel substrate and a liquid crystal panel equipped with this spacer, and a method for forming this spacer.

### Means for Solving the Problems

In order to solve the aforementioned problems, the spacer of the present invention is formed by laminating a plurality of subspacers including a first subspacer that has an opening in a center portion thereof in the plane direction, and a second subspacer that has a portion thereof partially overlapping the first subspacer and that has another portion thereof engaging the opening formed in the first subspacer.

A configuration where the aforementioned first subspacer is formed of a photosensitive material can be used.

A display panel substrate according to the present invention has the spacer that includes a first subspacer having an opening in a center portion thereof in the plane direction and a second subspacer having a portion thereof partially overlapping the first subspacer and having another portion thereof engaging in the opening formed in the first subspacer.

A configuration where the aforementioned first subspacer is formed of photosensitive materials can be used.

The display panel substrate according to the present invention includes colored patterns of a prescribed plurality of colors for a color display that are formed of a photosensitive material, and a spacer that includes a first subspacer having an opening in a center portion thereof in the plane direction and a second subspacer having a portion thereof partially overlapping the first subspacer and having another portion thereof engaging the opening in the first subspacer, wherein the first subspacer is formed of the same material as the colored pattern of one color among the colored patterns of the plurality of colors.

A configuration where the aforementioned second subspacer is formed of the same material as the colored pattern of a color that is different from that of the first subspacer can be employed.

A method for forming a spacer according to the present invention includes forming a first subspacer having an opening in a center portion thereof in the plane direction, and forming a second subspacer that is laminated such that a portion thereof engages the opening in the first subspacer, wherein, during the step of forming the first subspacer having the opening in the center portion thereof in the plane direction, a height of a top surface of the second subspacer is adjusted by adjusting dimensions of the opening in the first subspacer, and by therefore adjusting a volume of the portion of the second subspacer engaging the opening.

The method for forming a spacer may be configured such that the step of forming the first subspacer having the opening in the center portion thereof in the plane direction includes forming a photosensitive material film, exposing the photosensitive material film by radiating light energy to the photosensitive material film through a photomask that has a light-transmitting pattern and a light-shielding pattern corresponding to the first subspacer and to the opening in the first subspacer; and developing the photosensitive film that has undergone the exposure, wherein, during the exposure, dimensions of the opening in the first subspacer are adjusted by adjusting an amount of light energy radiated to a portion of the photosensitive material film where the light-shielding pattern of the photomask is projected.

The method of forming a spacer may also be configured such that the step of forming the first subspacer having the opening in the center portion thereof in the plane direction further includes steps of forming a positive type photosensitive material film, exposing the photosensitive material film by radiating light energy to the photosensitive material film through a photomask that has a light-shielding pattern corresponding to the first subspacer and a light-transmitting pattern corresponding to the opening to be formed in the first subspacer, and developing the photosensitive film that has undergone the exposure, wherein, during the exposure step, dimensions of the opening in the first subspacer are adjusted by adjusting an amount of light energy radiated to a portion of the positive type photosensitive material film where the light-shielding pattern of the photomask is projected, and by therefore adjusting a region of the photosensitive material film to be removed during the development step.

The method of forming a spacer may also be configured such that the step of forming the first subspacer having the opening in the center portion thereof in the plane direction further includes forming a negative type photosensitive material film, exposing the photosensitive material film by radiating light energy to the photosensitive material film through a photomask that has a light-transmitting pattern corresponding to the first subspacer and a light-shielding pattern corresponding to the opening to be formed in the first subspacer; and developing the photosensitive film that has undergone the exposure, wherein, during the exposure step, dimensions of the opening in the first subspacer are adjusted by adjusting an amount of light energy radiated to a portion of the negative type photosensitive material film where the light-shielding pattern of the photomask is projected, and by therefore adjusting a region of the photosensitive material film that is to be remained after the development step.

According to the present invention, a method for manufacturing a substrate for a display panel that has colored patterns of a prescribed plurality of colors includes steps of forming a first subspacer that has an opening in a center portion thereof in a plane direction simultaneously with a colored pattern of one color among the prescribed plurality of colors; and forming a second subspacer that is laminated such that a portion thereof engages the opening in the first subspacer simultaneously with a colored pattern of another color among the prescribed plurality of colors, wherein, during the step of forming the first subspacer having the opening in the center portion thereof in the plane direction, a height of a top surface of the second subspacer is adjusted by adjusting dimensions of the opening in the first subspacer, and by therefore adjusting a volume of the portion of the second subspacer engaging the opening.

The method of manufacturing a substrate for a display panel may also be configured such that the step of forming the first subspacer that has the opening in the center portion thereof in the plane direction simultaneously with the colored pattern of one color among the prescribed plurality of colors further includes steps of forming a photosensitive material film, exposing the photosensitive material film by radiating light energy to the photosensitive material film through a photomask that has a light-shielding pattern and a light-transmitting pattern that correspond to the colored pattern of one color and the first subspacer, and to the opening to be formed in the first subspacer; and developing the photosensitive film that has undergone the exposure, wherein, during the exposure step, the colored pattern of one color is formed, and dimensions of the opening in the first subspacer are adjusted by adjusting an amount of light energy radiated to a portion of the photosensitive material film where the light-shielding pattern of the photomask is projected.

The method for manufacturing a substrate for a display panel may also be configured such that the step of forming the first subspacer that has the opening in the center portion in the plane direction simultaneously with the colored pattern of one color among the prescribed plurality of colors further includes steps of forming a positive type photosensitive material film; exposing the photosensitive material film by radiating light energy to the photosensitive material film through a photomask that has a light-shielding pattern corresponding to the colored pattern of one color, a light-shielding pattern corresponding to the first subspacer, and a light-transmitting pattern corresponding to the opening to be formed in the first subspacer; and developing the positive type photosensitive film that has undergone the exposure, wherein, during the exposure step, the colored pattern of one color is formed, and dimensions of the opening in the first subspacer are adjusted by adjusting an amount of light energy radiated to a portion of the positive type photosensitive material film where the light-shielding pattern of the photomask is projected, and by therefore adjusting a region the photosensitive material film to be removed during the development step.

The method for manufacturing a substrate for a display panel may also be configured such that the step of forming the first subspacer that has the opening in the center portion in the plane direction simultaneously with the colored pattern of one color among the prescribed plurality of colors further includes forming a negative type photosensitive material film, exposing the negative type photosensitive material film by radiating light energy to the photosensitive material film through a photomask that has a light-transmitting pattern corresponding to the colored pattern of one color, a light-transmitting pattern corresponding to the first subspacer, and a light-shielding pattern corresponding to the opening to be formed in the first subspacer, and developing the negative type photosensitive film that has undergone the exposure, wherein, during the exposure step, the colored pattern of one color is formed, and dimensions of the opening in the first subspacer are adjusted by adjusting an amount of light energy radiated to a portion of the positive type photosensitive material film where the light-shielding pattern of the photomask is projected, and by therefore adjusting a region the photosensitive material film to be remained during the development step.

### Effects of the Invention

According to the present invention, it is possible to adjust the overall height of the spacer by adjusting the dimensions of the opening in the first subspacer. That is, it is possible to adjust the overall height of the spacer without adjusting the height dimension of the first subspacer or the second subspacer. With this configuration, it becomes possible to adjust the overall height of the spacer in a simpler manner as compared with a configuration of adjusting the thicknesses of the films that become the first subspacer and the second subspacer.

Furthermore, in the configuration of forming the first subspacer and the second subspacer of the same material as that of the colored pattern, the overall height of the spacer can be adjusted without changing the thickness of the colored pattern. This makes it possible to adjust the overall height of the spacer without adversely affecting the color characteristics of the colored patterns of the respective colors (that is, color characteristics of each pixel). That is, it becomes possible to adjust the color characteristics of the colored patterns of the respective colors and the overall height of the spacer independently without affecting each other.

The configuration of the display panel substrate according to the present invention differs from a configuration of adjusting a thickness of a black matrix so as to adjust the height dimension of the spacer in that the thickness of the black matrix does not affect the overall height of the spacer. That is, there is no need to adjust the thickness of the black matrix so as to adjust the overall height of the spacer. This makes it possible to employ a method that does not allow for the adjustment of the thickness of the black matrix, or a method in which it is difficult to adjust the thickness as a method for forming the black matrix.

The black matrix may be formed by the method of bonding (laminating) a film that includes black coloring agent to a transparent substrate, and patterning the bonded film, for example. In this method, the thickness of the black matrix is defined by the thickness of the film that is to be bonded (or a film that is to be laminated), and therefore, it is not possible to adjust the thickness.

As described, because there is no need to adjust the thickness of the black matrix during the step of forming the black matrix, the above-mentioned method that does not allow for the adjustment of the thickness of the black matrix may also be employed. This increases the number of alternative methods for forming the black matrix.

### BRIEF DESCRIPTION OF THE DRAWINGS

FIG. 1 is a drawing showing schematically the structure of a display panel substrate of an embodiment of the present invention. FIG. 1(a) is a perspective view showing schematically the overall structure of the display panel substrate of an embodiment of the present invention. FIG. 1(b) is a top view showing an extracted single pixel formed on the display panel substrate of an embodiment of the present invention. FIG. 1(c) is a cross-sectional drawing showing the cross-sectional structure of a pixel at the A-A line cross section of FIG. 1(b).

FIG. 2 is a drawing showing schematically the structure of a spacer of an embodiment of the present invention. FIG. 2(a) is a perspective view of the exterior of the spacer of an embodiment of the present invention, and FIG. 2(b) is a cross-sectional drawing of the spacer of an embodiment of the present invention.

FIG. 3 is a drawing showing schematically the structure of the spacer according to an embodiment of the present invention, and this drawing is an exploded perspective view of the spacer according to an embodiment of the present invention (common electrode omitted).

FIG. 4 is a cross-sectional drawing showing schematically the spacers of embodiments of the present invention having three types of height, and these drawings show schematically the relationship between the dimensions of the opening formed in the first subspacer and the overall height of the spacer according to an embodiment of the present invention. FIG. 4(a) shows a spacer according to an embodiment of the present invention that, among the three types, has the lowest height. FIG. 4(c) shows a spacer according to an embodiment of the present invention that, among the three types, has the highest height. FIG. 4(b) shows a spacer according to an embodiment of the present invention that, among the three types, has an intermediate height between the spacer according to an embodiment of the present invention shown in FIG. 4(a) and the spacer according to an embodiment of the present invention shown in FIG. 4(c).

FIG. 5 is a top schematic view showing a portion of the photomask (first photomask) used for forming the first subspacer of the spacer of an embodiment of the present invention.

FIG. 6 shows schematically a prescribed step of the method of formation of the spacer according to an embodiment of the present invention, and this drawing shows the step of forming the first film of photosensitive material, i.e., the raw material of the first subspacer of the spacer of an embodiment of the present invention.

FIG. 7 shows schematically a prescribed step of the method of formation of the spacer according to an embodiment of the present invention, and this drawing shows the step of exposure of the first film of photosensitive material.

FIG. 8 is a drawing showing schematically a prescribed step of the method of formation of the spacer according to an embodiment of the present invention, and this drawing schematically shows the step of development of the first film of photosensitive material (the photomask is also shown in order to show the dimensions of the formed first subspacer).

FIG. 9 is a graph showing schematically the relationship between the irradiation time of the light energy or the intensity of the irradiated light energy and the degree of light energy received by the first film of photosensitive material.

FIG. 10 is a top schematic view showing an extracted portion of the photomask (second photomask) used for forming the first subspacer of the spacer according to an embodiment of the present invention.

FIG. 11 is a drawing showing schematically a prescribed step of the method of formation of the spacer according to an embodiment of the present invention, and this drawing schematically shows the step of exposure of the second film of photosensitive material.

FIG. 12 is a drawing showing schematically a prescribed step of the method of formation of the spacer according to an embodiment of the present invention, and this drawing schematically shows the step of development of the second film of photosensitive material.

FIG. 13 is a graph showing schematically the relationship between the irradiation time of the light energy or the intensity of the irradiated light energy and the degree of light energy received by the second film of photosensitive material.

FIG. 14 shows cross-sectional drawings indicating schematically prescribed steps of the method of manufacture of the display panel substrate according to an embodiment of the present invention, FIG. 14(a) shows the black matrix formation step, and FIG. 14(b) shows the step of forming a certain color of colored pattern and the first subspacer of the spacer of an embodiment of the present invention.

FIG. 15 shows cross-sectional drawings indicating schematically prescribed steps of the method of manufacture of the display panel substrate according to an embodiment of the present invention, FIG. 15(a) shows the step of formation of the second color of the colored pattern and the second subspacer of the spacer of an embodiment of the present invention, and FIG. 15(b) shows the step of forming the third color of the colored pattern and the third subspacer of the spacer of an embodiment of the present invention.

FIG. 16 shows cross-sectional drawings indicating schematically prescribed steps of the method of manufacture of the display panel substrate according to an embodiment of the present invention, FIG. 16(a) shows the step of formation of the common electrode, and FIG. 16(b) shows the step of forming the orientation-determining structural member and the fourth subspacer of the spacer of an embodiment of the present invention.

### DETAILED DESCRIPTION OF EMBODIMENTS

Embodiments of the present invention will be described in detail below with reference to figures. A display panel substrate 1 of an embodiment of the present invention is a color filter that is used for a liquid crystal display panel. A spacer 2 of the embodiment of the present invention is one type of element (structure) formed in the display panel substrate 1 of an embodiment of the present invention, and has a function of determining the cell gap of the liquid crystal display.

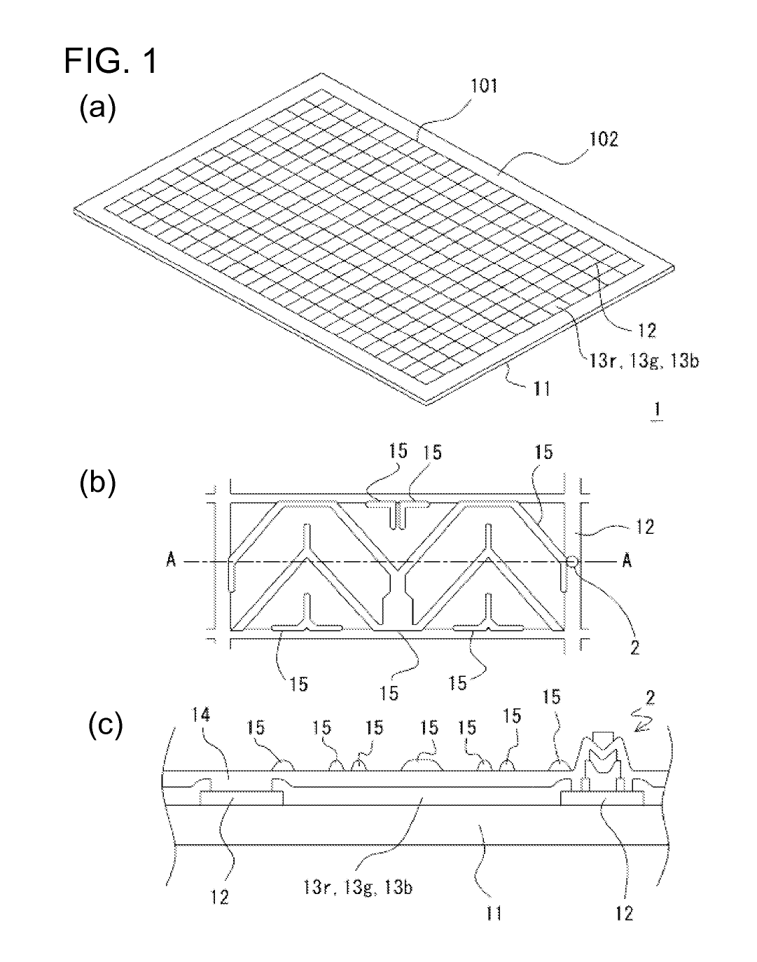

FIG. 1 is a drawing showing schematically the configuration of the display panel substrate 1 of an embodiment of the present invention. Specifically, FIG. 1(a) is an exterior perspective view showing schematically the overall structure of the display panel substrate 1 of an embodiment of the present invention. FIG. 1(b) is a top view showing an extracted single pixel formed on the display panel substrate 1 of the embodiment of the present invention. FIG. 1(c) is a cross-sectional drawing showing the cross-sectional structure of a pixel at the A-A line cross section of FIG. 1(b).

As shown in FIG. 1, a display region 101 (also referred to as a “pixel region”) and a panel frame region 102 are provided in the display panel substrate 1 of the embodiment of the present invention. The display region 101 is a region where pixels are arranged in a prescribed manner. The panel frame region 102 is a region arranged in the periphery of the display region 101, and encloses the display region 101.

As shown in FIG. 1, the display panel substrate 1 of the embodiment of the present invention has a transparent substrate 11 made of glass or the like. On the surface of this transparent substrate 11, a black matrix 12, colored patterns of prescribed colors 13r, 13g, and 13b, a spacer 2 of the embodiment of the present invention, a common electrode (also referred to as a “transparent electrode) 14, and an alignment control structure 15 are formed. Although other prescribed elements may be formed on the display panel substrate 1 of the embodiment of the present invention, illustrations and explanations thereof will be omitted. The display panel substrate 1 of the embodiment of the present invention may be configured in the same manner as a known color filter for a liquid crystal display panel except for the spacer 2 of the embodiment of the present invention.

The black matrix 12 in the display panel substrate 1 of the embodiment of the present invention can be configured in substantially the same manner as a black matrix of a typical color filter. The black matrix can be explained briefly as follows. The black matrix 12 is a film-shape element formed of a photosensitive material (a photosensitive resin composition made of acrylic resin or the like, for example) that includes a black coloring agent, for example. As shown in FIGS. 1(a) and 1(b), in particular, the black matrix 12 is formed in the display region 101 in substantially a grid pattern. The regions divided by the grid become openings of the respective pixels. In the panel frame region 102, the black matrix 12 is formed in a mask shape with a prescribed dimension and a prescribed shape so as to shield light in prescribed portions.

One of the red colored pattern 13r, the green colored pattern 13g, and the blue colored pattern 13b is selectively formed in each of the regions (opening of the pixel) divided by the black matrix 12. These colored patterns of the respective colors 13r, 13g, and 13b are respectively formed of photosensitive materials (photosensitive resin composition made of an acrylic resin or the like, for example) that respectively include coloring agents of red, green, and blue.

A common electrode 14 is formed on the surfaces of the black matrix 12 and the colored patterns of the respective colors 13r, 13g, and 13b (see FIG. 1(c), in particular). The common electrode 14 is a film shape element formed of a substantially transparent conductive material. Indium tin oxide (ITO), for example, can be used as the substantially transparent conductive material. A protective film may be formed on the surfaces of black matrix 12 and the colored patterns of respective colors 13r, 13g, and 13b so as to protect them, and the common electrode 14 may be formed on the surface of this protective film.

Alignment control structures 15 are formed on the surface of the common electrode 14. The alignment control structures 15 are protruding elements for controlling orientation of the liquid crystal. The alignment control structures 15 are formed of a photosensitive material (a photosensitive resin composition made of an acrylic resin or the like, for example).

The spacer 2 of the embodiment of the present invention is formed at a prescribed position on the black matrix 12. The spacer 2 of the embodiment of the present invention is a protruding element (structure) for controlling the cell gap of the liquid crystal display panel that includes the display panel substrate 1 of the embodiment of the present invention.

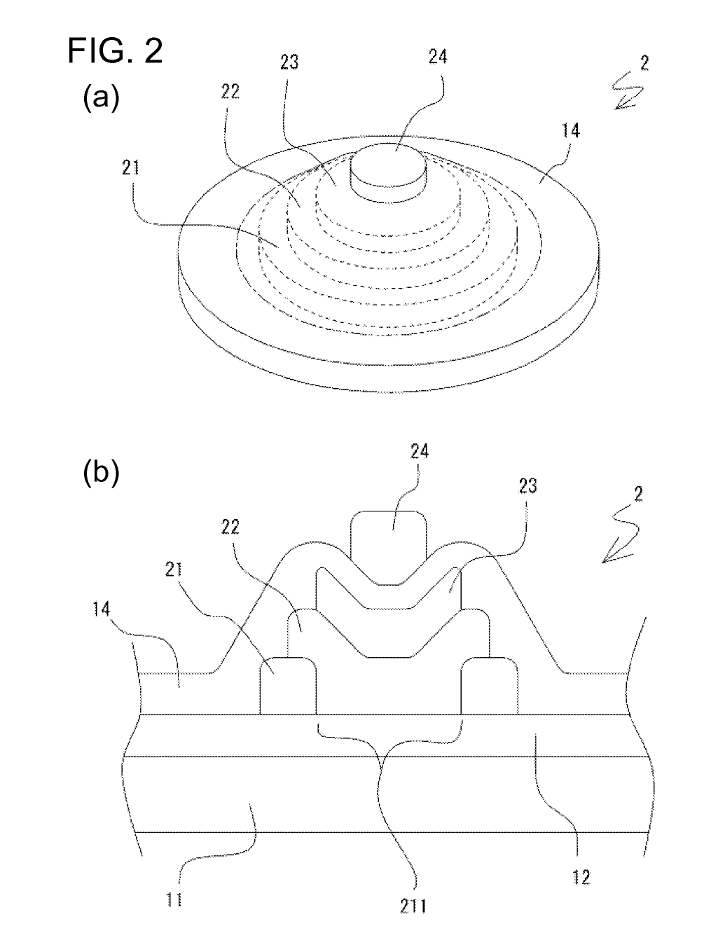

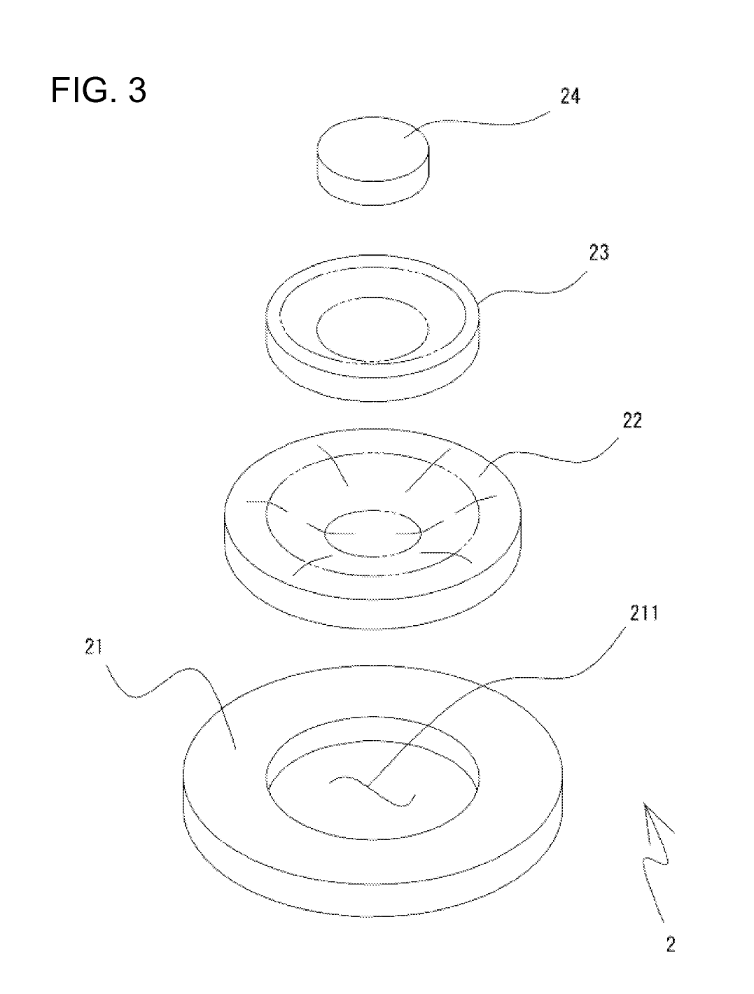

FIGS. 2 and 3 show schematically the structure of the spacer of the embodiment of the present invention. Specifically, FIG. 2(a) is an exterior perspective view of the spacer 2 of the embodiment of the present invention, and FIG. 2(b) is a cross-sectional drawing of the spacer 2 of the embodiment of the present invention. FIG. 3 is an exploded perspective view of the spacer 2 according to the embodiment of the present invention. The common electrode 14 is not shown in FIG. 3.

As shown respectively in FIGS. 2(a), 2(b), and 3, the spacer 2 of the embodiment of the present invention has a plurality of subspacers 21, 22, 23, and 24, and is constructed by laminating the plurality of subspacers 21, 22, 23, and 24. The spacer 2 has a prescribed overall height by the laminated plurality of subspacers 21, 22, 23, and 24. Although the spacer 2 of the embodiment of the present invention has the four layers of subspacers 21, 22, 23, and 24, for example, there is no limitation on the number of the subspacers 21, 22, 23, and 24. For the sake of convenient explanation, in order from the bottom side (the side closer to the transparent substrate 11), these subspacers are referred to as the first subspacer 21, the second subspacer 22, the third subspacer 23, and the fourth subspacer 24.

Although FIGS. 2(a), 2(b), and 3 show a configuration where the common electrode 14 is interposed between the third subspacer 23 and the fourth subspacer 24, a configuration without the common electrode 14 may also be employed.

Each subspacer 21, 22, 23, and 24 is formed of a photosensitive material. Specifically, the first subspacer 21, the second subspacer 22, and the third subspacer 23 are respectively formed of the same photosensitive materials as those of the colored patterns 13r, 13g, and 13b of the colors that are different from each other. The fourth subspacer 24 (the subspacer of the upper most layer) is formed of the same photosensitive material as that of the alignment control structures 15.

As shown in FIGS. 2(b) and 3, an opening 211 is formed in the center portion in the plane direction (hereinafter, referring to the plane direction of the transparent substrate 11) of the first subspacer 21. Thus, the first subspacer 21 is a ring-shaped or frame-shaped structure. The second subspacer 22 (the subspacer disposed immediately above (directly laminated on) the subspacer having the opening) is formed so as to have a dimension and shape that are larger than those of the opening 211 formed in the first subspacer 21 and that are smaller than the outer dimension and shape of the first subspacer 21. That is, when the second subspacer 22 is laminated on the first subspacer 21, the peripheral portion of the second subspacer 22 overlaps the first subspacer 21, and the center portion of the second subspacer 22 engages the opening 211 formed in the first subspacer 21.

There is no special limitation on the dimensions and shapes of the third subspacer 23 and the fourth subspacer 24. These dimensions and shapes may be substantially the same as those of the second subspacer 22, or may be smaller than those of the second subspacer 22, for example.

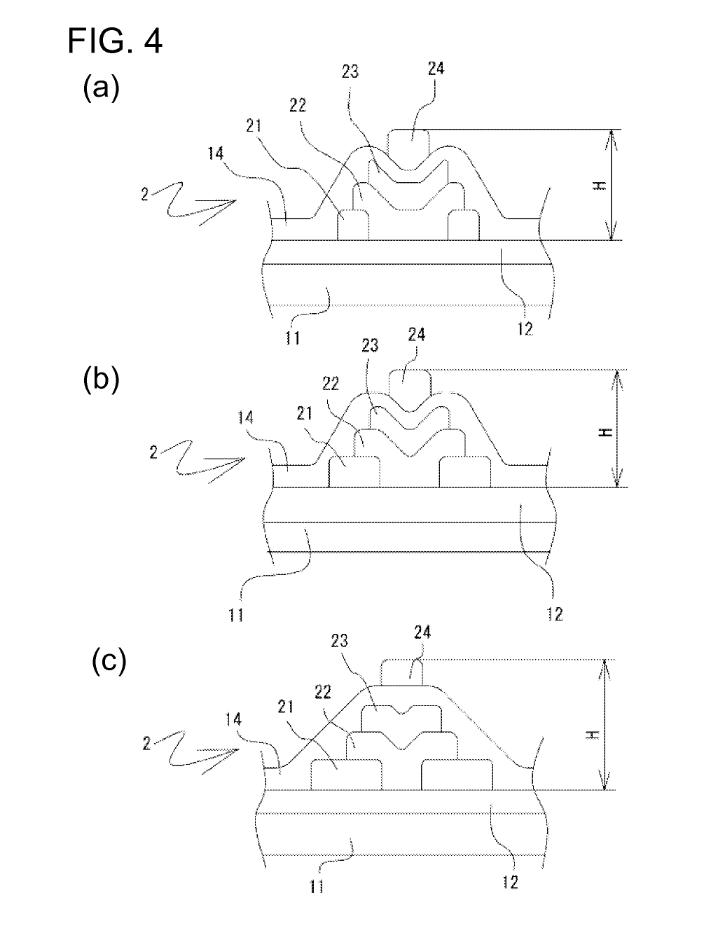

In FIG. 4, schematic cross-sectional views illustrating spacers of embodiments of the present invention having three types of height are shown. Each figure schematically shows a relationship between the dimension of the opening 211 formed in the first subspacer 21 and the overall height H of spacer 2 of the embodiment of the present invention. Specifically, FIG. 4(a) shows a spacer 2 according to the embodiment of the present invention that, among the three types, has the lowest height. FIG. 4(c) shows a spacer 2 according to the embodiment of the present invention that, among the three types, has the highest height. FIG. 4(b) shows a spacer 2 according to the embodiment of the present invention that, among the three types, has an intermediate height between that of the spacer 2 according to the embodiment of the present invention shown in FIG. 4(a) and the spacer 2 according to the embodiment of the present invention shown in FIG. 4(c).

As shown in FIGS. 4(a), 4(b), and 4(c), the spacer 2 of the embodiment of the present invention has a configuration where the second subspacer 22 is laminated on the first subspacer 21. The second subspacer 22 is configured such that the central portion thereof in the plane direction engages the opening 211 formed in the first subspacer 21. With this configuration, as the dimensions of the opening 211 formed in the first subspacer 21 become larger, the volume of the portion of the second subspacer 22 engaging the opening 211 in the first subspacer 21 becomes larger. As a result, the volume of the portion of the second subspacer 22 overlapping the first subspacer 21 becomes smaller, and thus the height of the upper surface (surface on the opposite side to the black matrix 12) of the second subspacer 22 from the black matrix 12 becomes shorter. When the height of the upper surface of the second subspacer 22 becomes smaller, the heights of the upper surfaces of the third subspacer 23 and fourth subspacer 24 laminated on the second subspacer 22 also become smaller, and therefore, the overall height of the spacer 2 of the embodiment of the present invention becomes smaller.

As described above, the overall height of the spacer 2 of the embodiment of the present invention becomes smaller as the dimensions of the opening 211 in the first subspacer 21 become larger, and the overall height becomes larger as the dimensions of the opening 211 formed in the first subspacer 21 become smaller. That is, the overall height of the spacer 2 of the embodiment of the present invention changes so as to follow a change in dimensions of the opening 211 formed in the first subspacer 21. Thus, by adjusting the dimensions of the opening 211 formed in the first subspacer 21, the overall height of the spacer 2 of the embodiment of the present invention can be adjusted. The adjustment of the overall height of the spacer 2 of the embodiment of the present invention allows the cell gap of the liquid crystal display panel that includes the display panel substrate 1 of the embodiment of the present to be adjusted and therefore maintained at a prescribed value.

The method of forming the spacer 2 of the embodiment of the present invention will be explained next.

The spacer 2 of the embodiment of the present invention is formed as the first subspacer 21, the second subspacer 22, the third subspacer 23, and the fourth subspacer 24 in this order. The subspacers 21, 22, 23, and 24 are respectively formed of a photosensitive material by the photolithography to have prescribed dimensions and shapes. The photosensitive material may be either a positive type or negative type.

First, the method of forming the first subspacer 21 using a positive type photosensitive material will be explained. The portion of a positive type photosensitive material irradiated by light energy during exposure treatment is removed by dissolution by the developing solution during developing treatment.

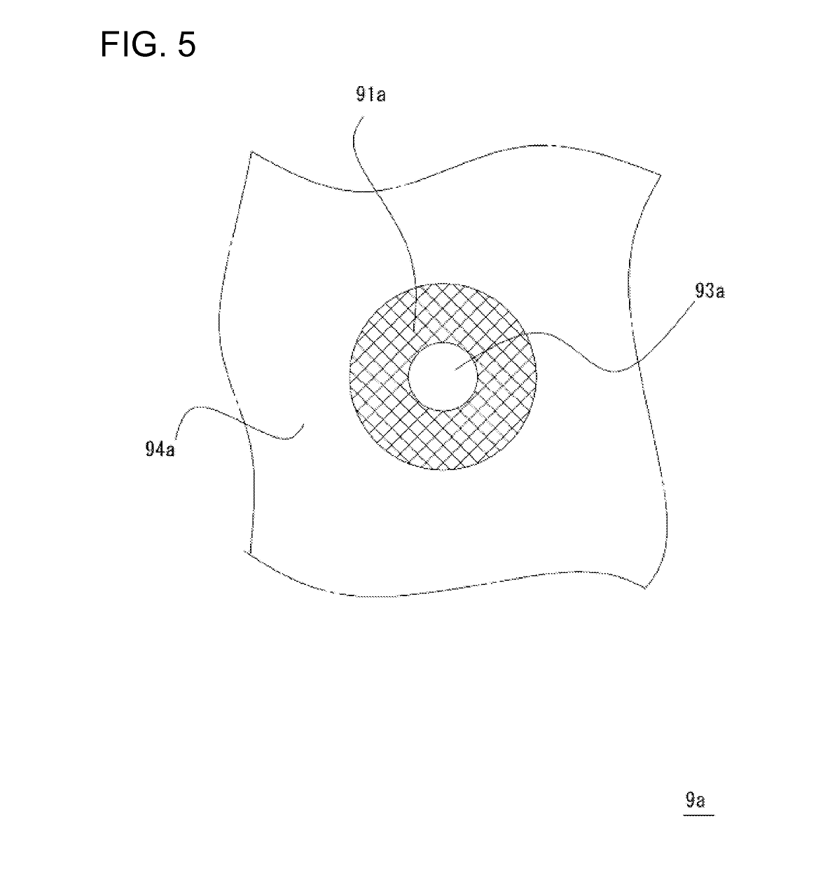

FIG. 5 is a top schematic view showing an extracted portion of a photomask 9a used for forming the first subspacer 21 of the spacer 2 of the embodiment of the present invention. For convenience in the description, the photomask 9a will be referred to as a “first photomask” 9a.

A light-shielding pattern 91a having dimensions and shape corresponding to the first subspacer 21 is formed in the first photomask 9a as shown in FIG. 5. That is to say, the light-shielding pattern 91 a is formed as a ring shape or frame shape having prescribed dimensions and shape. When a contact exposure device or a proximity exposure device is used, for example, a light-shielding pattern 91a having substantially the same dimensions and shape as those of the first subspacer 21 is formed in the first photomask 9a. When a projection exposure device is used, a light-shielding pattern 91a having dimensions corresponding to the magnification factor and formed with a shape substantially similar to that of the first subspacer 21 is formed in the first photomask 9a. Then the light-transmitting patterns 93a and 94a are respectively formed inside and outside of the light-shielding pattern 91a. For convenience in the description, the reference numeral “93a” is assigned to the light-transmitting pattern formed inside of the light-shielding pattern 91a, and the reference numeral “94a” is assigned to the light-transmitting pattern formed outside of the light-shielding pattern 91a. The light-shielding pattern 91a is a pattern that is capable of blocking light energy emitted from the light source of the exposure device.

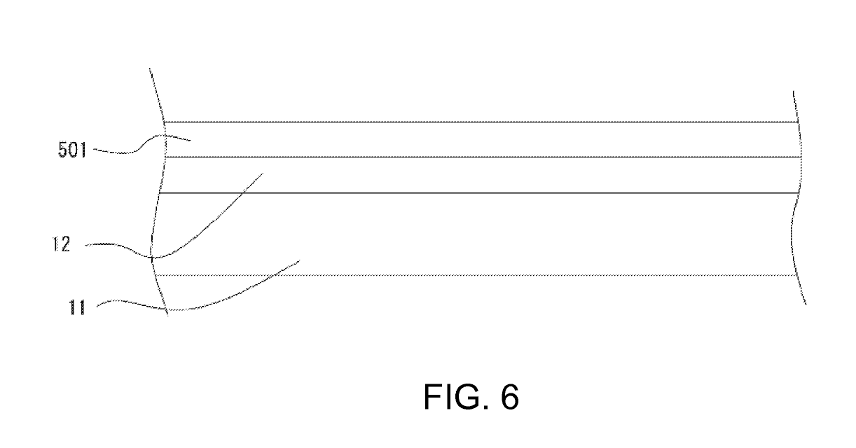

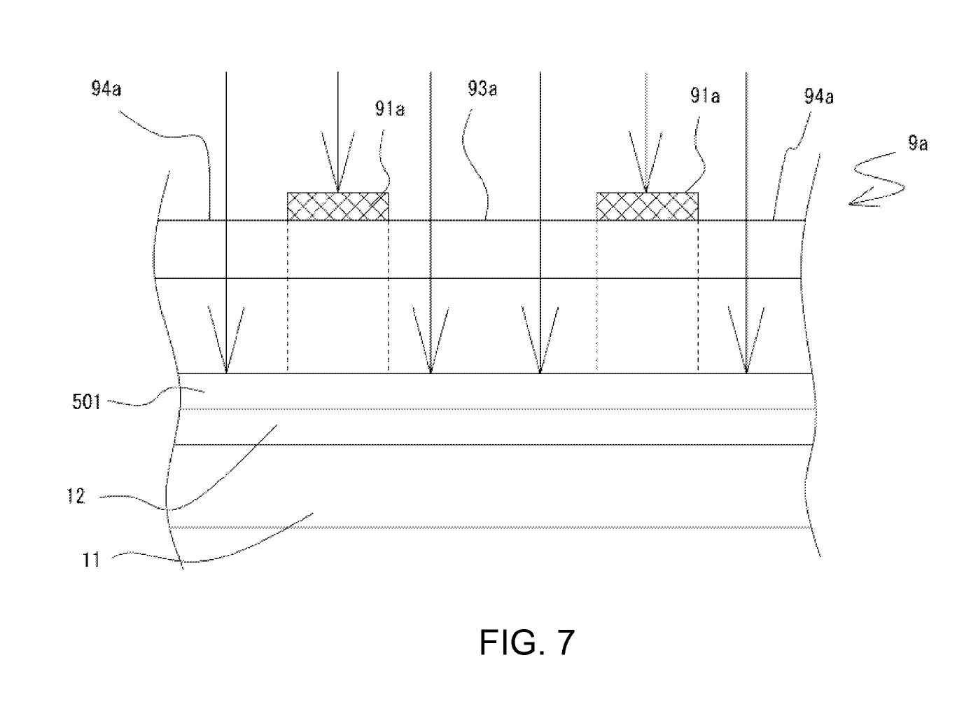

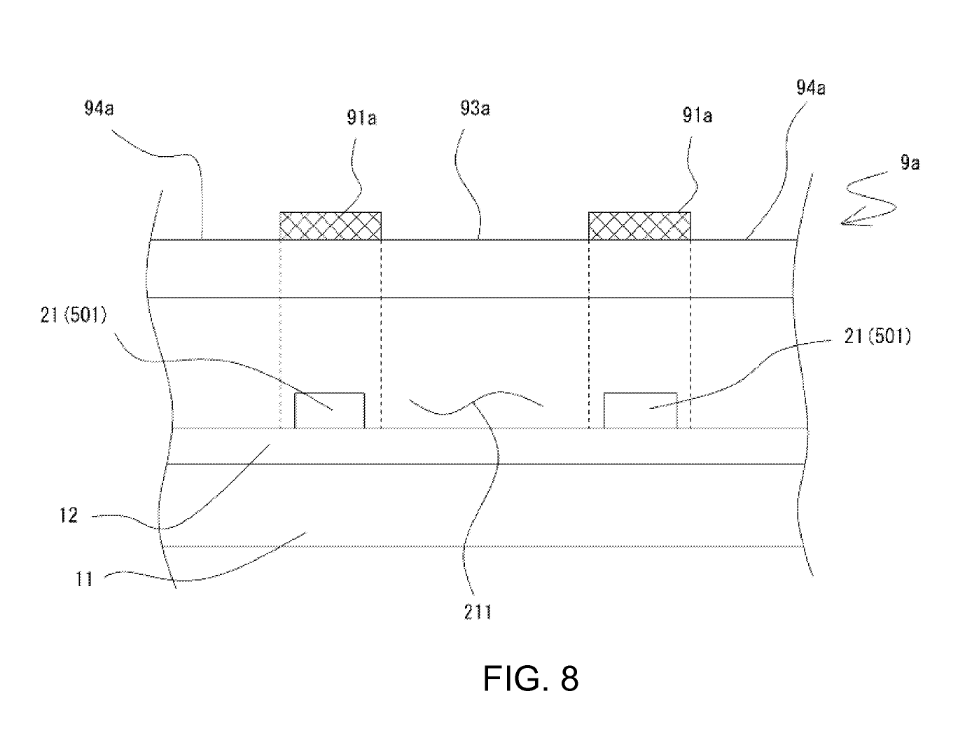

FIGS. 6 to 8 are drawings showing schematically respective prescribed steps of the method of forming the spacer 2 of the embodiment of the present invention. Specifically, FIG. 6 is a drawing showing the step of forming a first photosensitive material film 501, which is the material of the first subspacer 21 of the spacer 2 of the embodiment of the present invention. FIG. 7 is a drawing showing the exposure step of the first photosensitive material film 501. FIG. 8 is a drawing showing schematically the development step of the first photosensitive material film 501. In FIG. 8, the first photomask 9a is also shown so as to indicate dimensions of the formed first subspacer 21.

First, the first photosensitive material film 501 is formed on the surface of the black matrix 12 as shown in FIG. 6. The first photosensitive material film 501 is the material of the first subspacer 21 of the spacer 2 of the embodiment of the present invention. There is no special limitation on the method of forming the first photosensitive material film 501, and various types of conventionally known methods can be used. A method such as applying a solution that is a material of the first photosensitive material film 501 to the surface of the black matrix using a slit coater, spin coater, or the like, and thereafter drying this solution so as to volatilize the solvent for solidification can be used, for example.

Thereafter, as shown in FIG. 7, the first photosensitive material film 501 that has been formed undergoes the exposure treatment using the first photomask 9a. FIG. 6 shows a configuration in which a proximity exposure device (not shown) is used (a configuration in which the first photomask 9a is placed with a very small distance from the first photosensitive material film 501 that is to be exposed) as an example. However, a configuration in which a contact exposure device is used, or a configuration in which a projection exposure device is used may also be employed.

As shown in FIG. 7, light energy is radiated to portions of the first photosensitive material film 501 where the light-transmitting patterns 93a and 94a of the first photomask 9a are projected. On the other hand, overall, light energy is not radiated to a portion where the light-shielding pattern 91a of the first photomask 9a is projected. However, because the light energy that has passed through the light-transmitting patterns 93a and 94a formed inside and outside of the light-shielding pattern 91a spreads, the portion where the light-shielding pattern 91a of the first photomask 9a is projected may be irradiated with the light energy, even though the irradiation amount is smaller than that of the portions where the light transmitting patterns 93a and 94a are projected. The irradiation amount of the spread light energy becomes gradually smaller with distance from the respective boundaries with the light-transmitting patterns 93a and 94a.

Thereafter, as shown in FIG. 8, the first photosensitive material film 501 after the exposure process undergoes the development treatment. During development treatment, the portions of the first photosensitive material film 501 where the light-transmitting patterns 93a and 94a of the first photomask 9a were projected (portions irradiated with the light energy through the light-transmitting patterns 93a and 94a) are resolved in a development solution and are therefore removed from the surface of the black matrix 12. On the other hand, the portion where the light-shielding pattern 91a of the first photomask 9a was projected (portion that was not irradiated with the light energy due to the light-shielding pattern 91a blocking the light energy) is not dissolved in the development solution, and mostly remains on the surface of the black matrix 12. The remaining first photosensitive material film 501 becomes the first subspacer 21 of the spacer 2 of the embodiment of the present invention.

However, in the portion where the light-shielding pattern 91a was projected, a portion in the vicinity of the boundaries with the portions where the light-transmitting patterns 93a and 94a were projected may be dissolved in the developing solution, and may be removed from the surface of the black matrix 12 during the development step. Thus, as shown in FIG. 8, the dimensions of the opening 211 formed in the first subspacer 21 may become larger than the dimensions of the portion where the light transmitting pattern 93a, which is formed inside of the light-shielding pattern 91a of the first photomask 9a, was projected.

Such a dimensional difference is caused due to the following reasons. In the positive type photosensitive material, when the irradiation amount of light energy exceeds a prescribed threshold value (so-called “resist sensitivity”), the photosensitive material becomes soluble in the development solution during the development step. As described above, the portion of the first photosensitive material film 501 where the light-shielding pattern 91a of the first photomask 9a was projected is irradiated with the light energy that spread after passing through the light-transmitting patterns 93a and 94a. However, even though the portion is irradiated with the light energy that spread after passing through the light-transmitting patterns 93a and 94a, if the irradiation amount does not exceed the aforementioned threshold value, the film is not dissolved in the development solution during the development step, and remains on the surface of the black matrix 12. However, when the irradiation amount of the light energy that spread after passing through the light-transmitting patterns 93a and 94a exceeds the aforementioned prescribed threshold value, even though the light-shielding pattern 91a was projected in the portion, the portion is dissolved in the development solution, and is therefore removed during the development step.

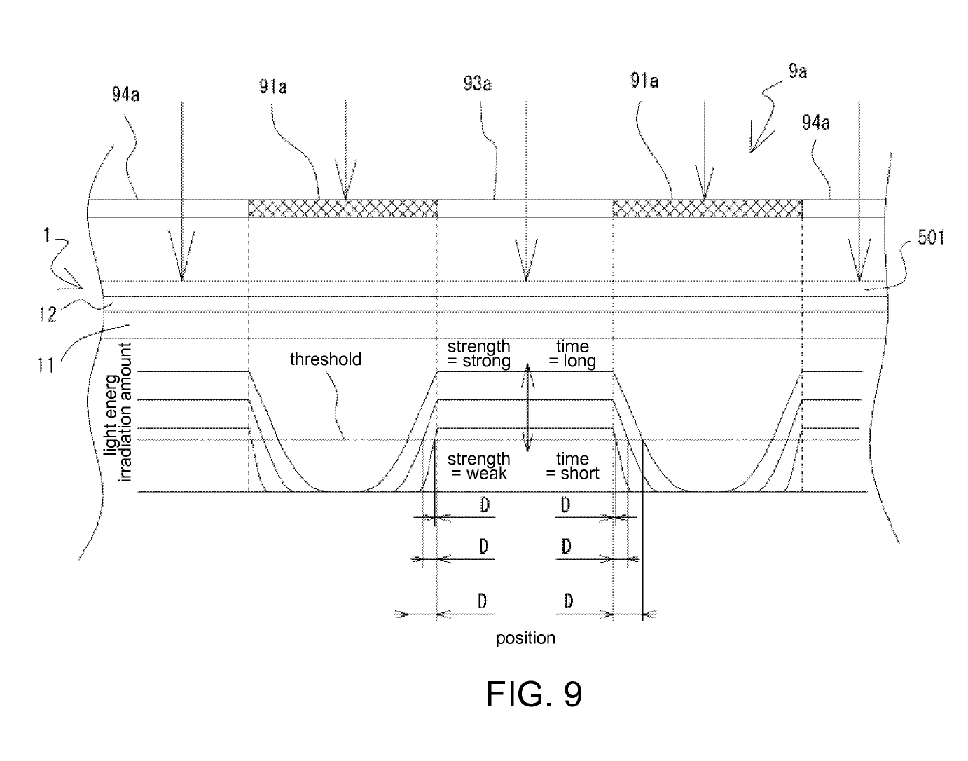

FIG. 9 is a graph showing schematically a relationship between the irradiation time of light energy or intensity of the irradiated light energy and the amount of light energy radiated to the first photosensitive material film 501. As shown in FIG. 9, the irradiation amount of the spread light energy in the portion where the light-shielding pattern 91 a of the first photomask 9a is projected is at the highest level at the boundaries between the portion where the light-transmitting patterns 93a and 94a were projected and the portion where the light-shielding pattern 91a was projected, and gradually decreases with distance from these boundaries. As the light energy emitted from the light source of the exposure device becomes stronger or the irradiation time of the light energy becomes longer, an area D of the portion where the light-shielding pattern 91a of the first photomask 9a is projected, which was irradiated with the greater amount of light energy then the prescribed threshold value, becomes larger. That is, the area D that was irradiated with the greater amount of light energy than the prescribed threshold value expands from the respective boundaries between the portions where the light-transmitting patterns 93a and 94a were projected and the portion where the light-shielding pattern 91a was projected toward the inward side of the portion where the light-shielding pattern 91a was projected.

Because the area D that was irradiated with the greater amount of spread light energy than the prescribed threshold value is removed in the development process, when the area D changes, an area to be dissolved in the development solution and to be therefore removed in the development process is changed. This causes the dimensions of the opening 211 formed in the first subspacer 21 to change.

Thus, by making the light energy intensity higher, or by making the irradiation time of the light energy longer (or by making the light energy intensity higher and the irradiation time of the light energy longer), the dimensions of the opening 211 formed in the first subspacer 21 can be increased. In contrast, by making the intensity lower, or by making the irradiation time shorter (or by making the intensity lower and the irradiation time shorter), the dimensions of the opening 211 can be reduced. As described, during the exposure step, by adjusting at least the intensity of the light energy generated by the light source of the exposure device or the irradiation time of the light energy, the dimensions of the opening 211 formed in the first subspacer 21 can be adjusted.

In this configuration, the dimensions of the opening 211 formed in the first subspacer 21 become greater than or equal to the dimensions of the portion where the light-transmitting pattern 93a formed inside of the light-shielding pattern 91a of the first photomask 9a. Therefore, the dimensions of the light-shielding pattern 91a of the first photomask 9a and the light-transmitting pattern 93a formed inside thereof are determined on a basis of the minimum dimensions of the opening 211 formed in the first subspacer 21.

Thereafter, the second subspacer 22 is laminated on the first subspacer 21 that has been formed (see FIGS. 2 and 3). The second subspacer 22 is formed of a photosensitive material. Various known photolithography methods can be used for forming the second subspacer 22. That is, a film of photosensitive material, which is the material of the second subspacer 22, is formed on the surface of the transparent substrate 11 where the first subspacer 21 has been formed. Thereafter, the second photosensitive material film is patterned by the photolithography so as to remove undesired portions, and the remaining portion that was not removed becomes the second subspacer 22. The detailed explanation of the method for forming the second subspacer 22 will be omitted.

The peripheral edge portion of the second subspacer 22 overlaps the first subspacer 21, and the center portion fits in the opening 211 formed in the first subspacer 21. Thus, the height of the upper surface of the second subspacer 22 (referring to a distance from the surface of the black matrix 12 to the surface thereof on a side opposite to the black matrix 12 and the first subspacer 21; the same will apply hereinafter) varies in accordance with the volume of the portion fitted into the opening 211 formed in the first subspacer 21. That is, as the volume of the portion fitted into the opening 211 formed in the first subspacer 21 becomes larger, the overall height of the upper surface of the second subspacer 22 becomes lower. When this volume becomes smaller, the overall height of the upper surface of the second subspacer 22 becomes higher. The volume of the portion of the second subspacer 22 fitted into the opening 211 formed in the first subspacer 21 is determined by the dimensions of the opening 211 formed in the first subspacer 21. Thus, by adjusting the dimensions of the opening 211 formed in the first subspacer 21, the height of the upper surface of the second subspacer 22 can be adjusted.

The third subspacer 23 is laminated on the second subspacer 22, and the fourth subspacer 24 is laminated on the third subspacer 23. As shown in FIGS. 2 and 3, a common electrode 14 is formed between the third subspacer 23 and the fourth subspacer 24 (a configuration without the common electrode 14 is also possible). The third subspacer 23 and the fourth subspacer 24 are formed of a photosensitive material. The third subspacer 23 and the fourth subspacer 24 may be formed by various known photolithography methods. Thus, an explanation thereof will be omitted.

When the height of the upper surface of the second subspacer 22 changes, heights of the upper surfaces of the third subspacer 23 and the fourth subspacer 24 also change. This causes the overall height H of the spacer 2 of the embodiment of the present invention to change. As described above, by adjusting the dimensions of the opening 211 formed in the first subspacer 21, the overall height of the spacer 2 of the embodiment of the present invention can be adjusted.

The method of forming the first subspacer 21 using a negative type photosensitive material will be explained next. In the negative type photosensitive material, a portion irradiated with light energy during exposure treatment is not dissolved in the development solution in the development process, and therefore remains.

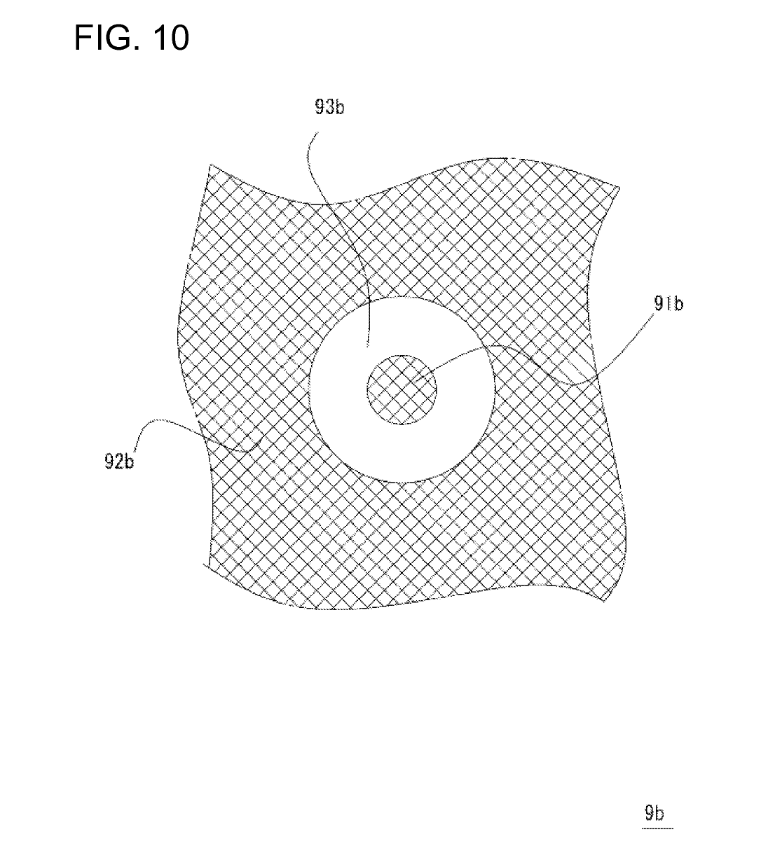

FIG. 10 is a top view schematically showing an extracted portion of the photomask 9b used for forming the first subspacer 21 of the spacer 2 of the embodiment of the present invention. For convenience in the description, the photomask 9b will be referred to as a “second photomask” 9b.

As shown in FIG. 10, a light-transmitting pattern 93b having dimensions and shape corresponding to the first subspacer 21 is formed in the second photomask 9b. The light-transmitting pattern 93b is formed into a ring shape or frame shape having prescribed dimensions and shape. That is to say, when a contact exposure device or a proximity exposure device is used, for example, a light-transmitting pattern 93b having substantially the same dimensions and shape as those of the first subspacer 21 is formed in the second photomask 9b. When a projection exposure device is used, a light-transmitting pattern 93b having dimensions corresponding to the magnification factor and a shape substantially similar to that of the first subspacer 21 is formed in the second photomask 9b. The light-shielding patterns 91b and 92b are formed inside and outside of the light-transmitting pattern 93b, respectively. For convenience in the description, the reference numeral “91b” is assigned to the light-shielding pattern formed inside of the light-transmitting pattern 93b, and the reference numeral “92b” is assigned to the light-shielding pattern formed outside of the light-transmitting pattern 93b. The light-shielding patterns 9 lb and 92b are patterns that are capable of blocking light energy emitted from the light source of the exposure device. The light-transmitting pattern 93b is a pattern that is capable of transmitting light generated by the light source of the exposure device.

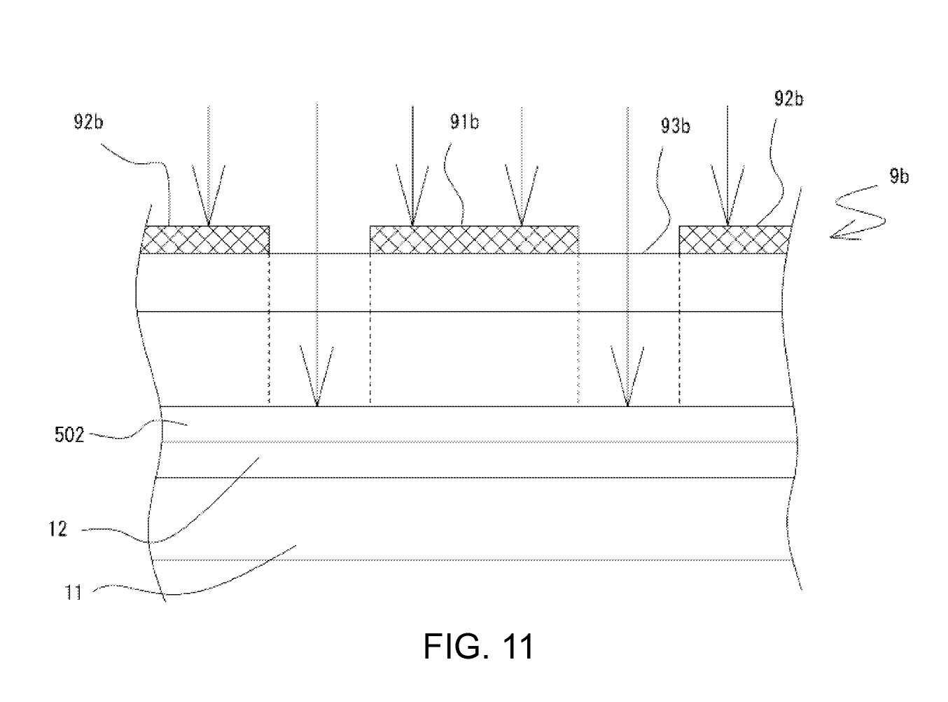

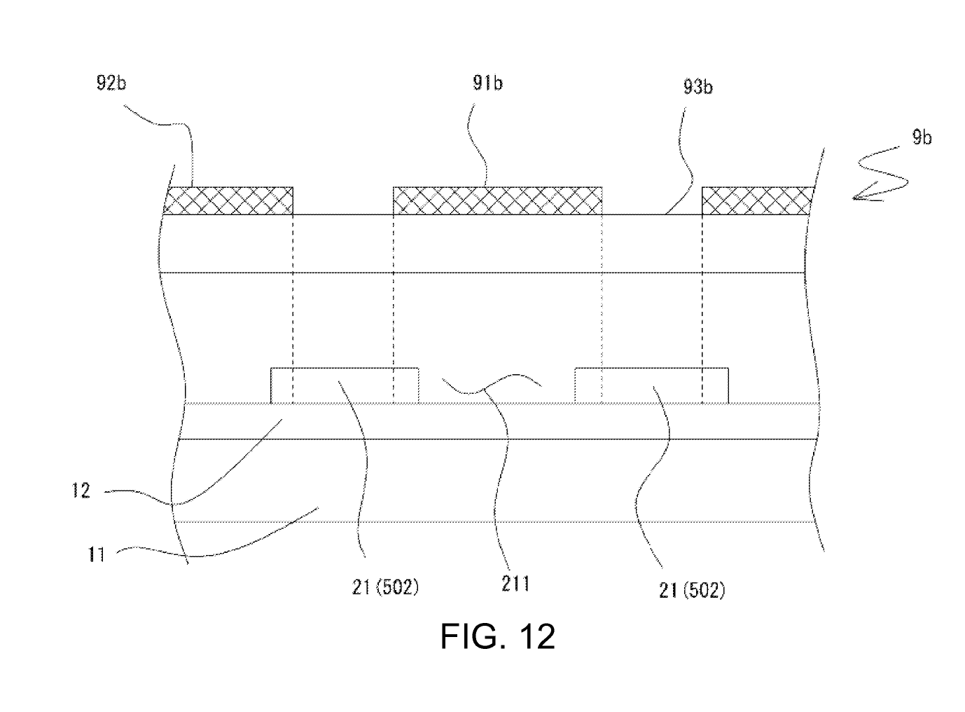

FIGS. 11 and 12 are drawings showing schematically respective prescribed steps of the method of forming the spacer 2 of the embodiment of the present invention. Specifically, FIG. 11 is a drawing showing the exposure step of the second photosensitive material film 502, and FIG. 12 is a drawing showing the development step of the second photosensitive material film 502.

First, the second photosensitive material film 502 is formed on the surface of the black matrix 12 (see FIG. 6). The second photosensitive material film 502 is the material of the first subspacer 21 of the spacer 2 of the embodiment of the present invention. The second photosensitive material film 502 may be formed by the same method as that of the first photosensitive material film 501.

Thereafter, as shown in FIG. 11, the formed second photosensitive material film 502 undergoes the exposure treatment using the second photomask 9b. Although FIG. 11 shows a configuration where a proximity exposure device is used as an example, a configuration where a contact exposure device is used, or a configuration where a projection exposure device is used may also be employed.

As shown in FIG. 11, the light energy generated by the light source of the exposure device is radiated to a portion of the second photosensitive material film 502 where the light-transmitting pattern 93b of the second photomask 9b is projected. On the other hand, light energy is not radiated to entire portions where the light-shielding patterns 91b and 92b of the second photomask 9b are projected. However, because the light energy may spread after passing through the light-transmitting pattern 93b, the portions where the light-shielding patterns 91b and 92b of the second photomask 9b are projected may be irradiated with light energy, even though the irradiation amount becomes smaller than that of the portion where the light-transmitting pattern 93b is projected. The irradiation amount of the spread light energy becomes gradually smaller with distance from the boundaries with the light-transmitting pattern 93b.

After the exposure treatment, as shown in FIG. 12, the second photosensitive material film 502 undergoes a development treatment. During the development treatment, the portions of the second photosensitive material film 502 where the light-shielding patterns 91b and 92b of the second photomask 9b were projected (portions that were not irradiated due to the light-shielding patterns 91b and 92b blocking the light energy) are dissolved in the development solution, and are therefore removed as a whole from the surface of the black matrix 12. On the other hand, the portion where the light-transmitting pattern 93b of the second photomask 9b was projected (portion where light energy was radiated through the light-transmitting pattern 93b) is not dissolved in the development solution, and remains on the surface of the black matrix 12. The remaining second photosensitive material film 502 becomes the first subspacer 21 of the spacer 2 of the embodiment of the present invention.

However, in the portions where the light-shielding patterns 91b and 92b were projected, portions thereof in the vicinity of the respective boundaries with the portion where the light-transmitting pattern 93b was projected are not dissolved in the development solution during the development step, and remain on the surface of the black matrix 12. Thus, as shown in FIG. 12, the dimensions of the opening 211 formed in the first subspacer 21 become smaller than the dimensions of the portion where the light-shielding pattern 91b, which is formed inside of the light-transmitting pattern 93b of the second photomask 9b, was projected.

Such a dimensional difference is caused due to the following reasons. In the negative type photosensitive material, when the irradiation amount of light energy exceeds a prescribed threshold value (the resist sensitivity), the photosensitive material becomes insoluble in the development solution during the development step. As described above, the portions of the second photosensitive material film 502 where the light-shielding patterns 91b and 92b of the second photomask 9b are projected are irradiated with the light energy that spread after passing through the light-transmitting pattern 93b. However, even though the portion is irradiated with the light energy that spread after passing through the light-transmitting pattern 93b, when the irradiation amount does not exceed the prescribed threshold value, the film is dissolved in the development solution, and therefore is removed from the surface of the black matrix 12 during the development step. However, when the irradiation amount of the light energy that spread after passing through the light-transmitting pattern 93b exceeds the prescribed threshold value, the portion becomes insoluble to the development solution in the development process even though the light-shielding patterns 91b and 92b were projected thereon.

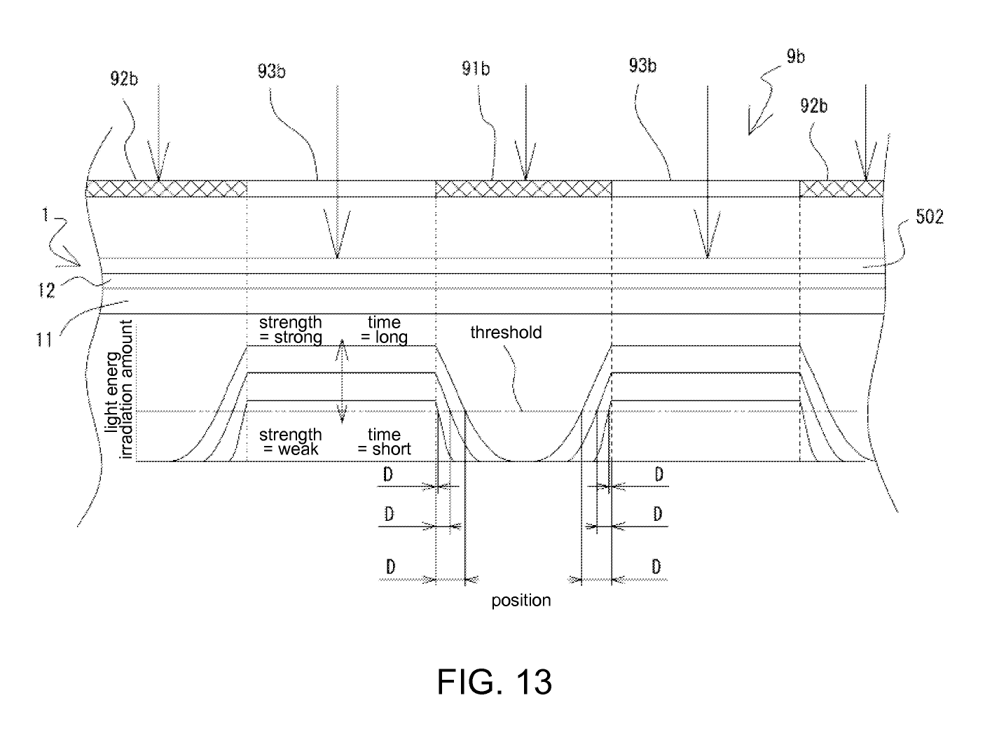

FIG. 13 is a graph showing schematically a relationship between irradiation time of light energy or intensity of the irradiated light energy and the amount of light energy radiated to the second photosensitive material film 502. As shown in FIG. 13, in the portions where the light-shielding patterns 91b and 92b of the second photomask 9b were projected, the irradiation amount of light energy is at the highest level at the respective boundaries between the portions where the light-shielding patterns 91b and 92b are projected and the portion where the light-transmitting pattern 93b is projected, and gradually decreases with distance from the boundaries. When the intensity of the light energy emitted from the light source of the exposure device becomes higher, or the irradiation time of the light energy becomes longer (or when both the intensity of the light energy becomes stronger and the irradiation time becomes longer), the areas D of the portions where the light-shielding patterns 91b and 92b of the second photomask 9b were projected, which were irradiated with the greater amount of light energy than the prescribed threshold value, becomes larger. That is to say, the areas D that received the greater amount of irradiation light than the prescribed threshold value expands from the respective boundaries between the portions where the light-shielding patterns 91b and 92b were projected and the portion where the light-transmitting pattern 93b was projected toward the inward sides of the portions where the light-shielding patterns 91b and 92b were projected.

The areas D that were irradiated with the greater amount of the spread light energy than the prescribed threshold value are not dissolved in the development solution in the development process, and therefore remain. Therefore, when this area D changes, the area of the portion that is not dissolved in the development solution during the development process and therefore remains also changes, which causes the dimensions of the opening 211 formed in the first subspace 21 to change. That is, by making the intensity of the light energy emitted from the light source higher, or by making the irradiation time of the light energy longer (or by making the light energy intensity stronger and the irradiation time longer), the dimensions of the opening 211 formed in the first subspacer 21 can be reduced. In contrast, by making the intensity lower, or by making the irradiation time becomes shorter, the dimensions of the opening 211 can be increased. As described above, during the exposure step, by adjusting at least one of the intensity of the light energy generated by the light source of the exposure device and the irradiation time of the light energy, the dimensions of the opening 211 formed in the first subspacer 21 can be adjusted.

In such a configuration, the dimensions of the opening 211 formed in the first subspacer 21 become smaller than or equal to the dimensions of the portion where the light-shielding pattern 91b formed inside of the light-transmitting pattern 93b of the second photomask 9b. Thus, dimensions of the light-transmitting pattern 93b of the second photomask 9b and the light-shielding pattern 91b formed inside thereof are determined on a basis of the maximum dimensions of the opening 211 formed in the first subspacer 21.

Thereafter, the second subspacer 22 is laminated on the first subspacer 21 that has been formed. Further, the third subspacer 23 is laminated on the second subspacer 22, and the fourth subspacer 24 is laminated on the third subspacer 23. The second subspacer 22, the third subspacer 23, and the fourth subspacer 24 may be formed by using the same method as the method of forming the first subspacer 21 of the positive type photosensitive material (see FIGS. 2 and 3). A configuration of adjusting the overall height of the spacer 2 of the embodiment of the present invention through the adjustment of the dimensions of the opening 211 formed in the first subspacer 21 is also same as the configuration where the first subspacer 21 is formed of the positive type photosensitive material. Therefore, explanations thereof will be omitted.

As described above, both the positive type photosensitive resin material and the negative type photosensitive resin material can be used as the material of the first subspacer 21.

The following operational effects can be obtained by the spacer 2 of the embodiment of the present invention.

The overall height H of the spacer 2 of the embodiment of the present invention can be adjusted through the adjustment of the dimensions of the opening 211 formed in the first subspacer 21. This makes it possible to adjust the overall height H of the spacer 2 of the embodiment of the present invention without adjusting the height dimensions of the respective subspacers 21, 22, 23, and 24 of the spacer 2 of the embodiment of the present invention. With this configuration, it is possible to adjust the overall height H of the spacer 2 of the embodiment of the present invention in a simpler manner than adjusting the thicknesses of the photosensitive materials films of the respective subspacers 21, 22, 23, and 24.

Furthermore, in a configuration where the respective subspacers 21, 22, 23, and 24 are formed of the same material as that of the colored patterns 13r, 13g, and 13b, it is possible to adjust the overall height of the spacer 2 of the embodiment of the present invention without changing the thicknesses of the colored patterns 13r, 13g, and 13b. Therefore, it becomes possible to adjust the overall height H of spacer 2 of the embodiment of the present invention without affecting the color characteristics (i.e., color characteristic of each pixel) of the colored patterns 13r, 13g, and 13b of the respective colors. That is to say, it is possible to independently adjust the color characteristics of the colored patterns 13r, 13g, and 13b of the respective colors and the overall height H of the spacer 2 of the embodiment of the present invention without affecting each other.

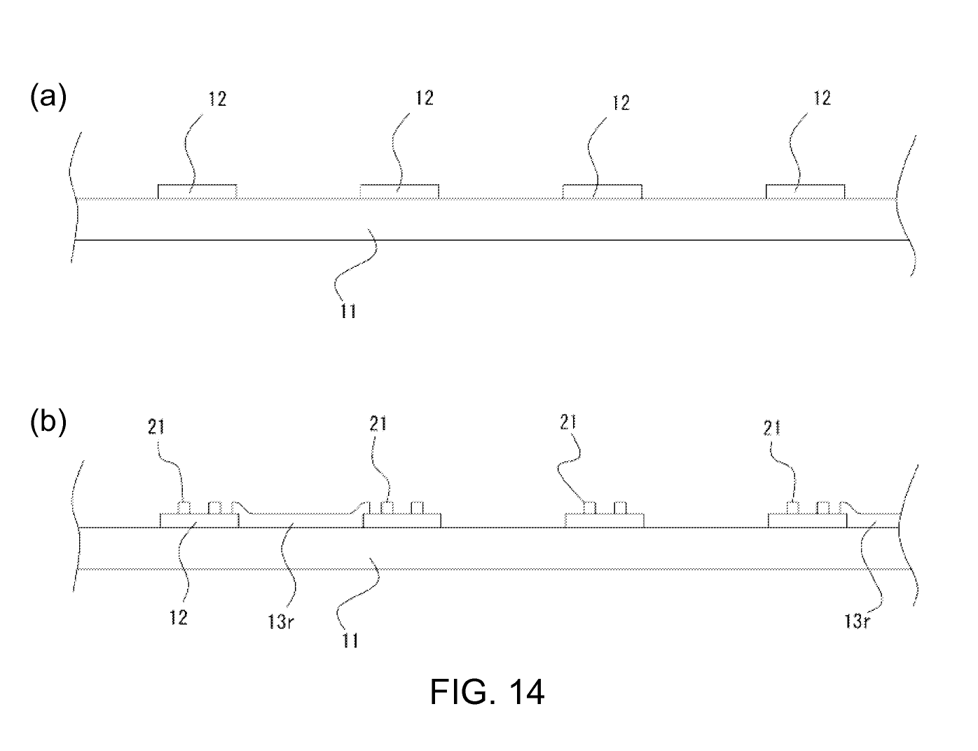

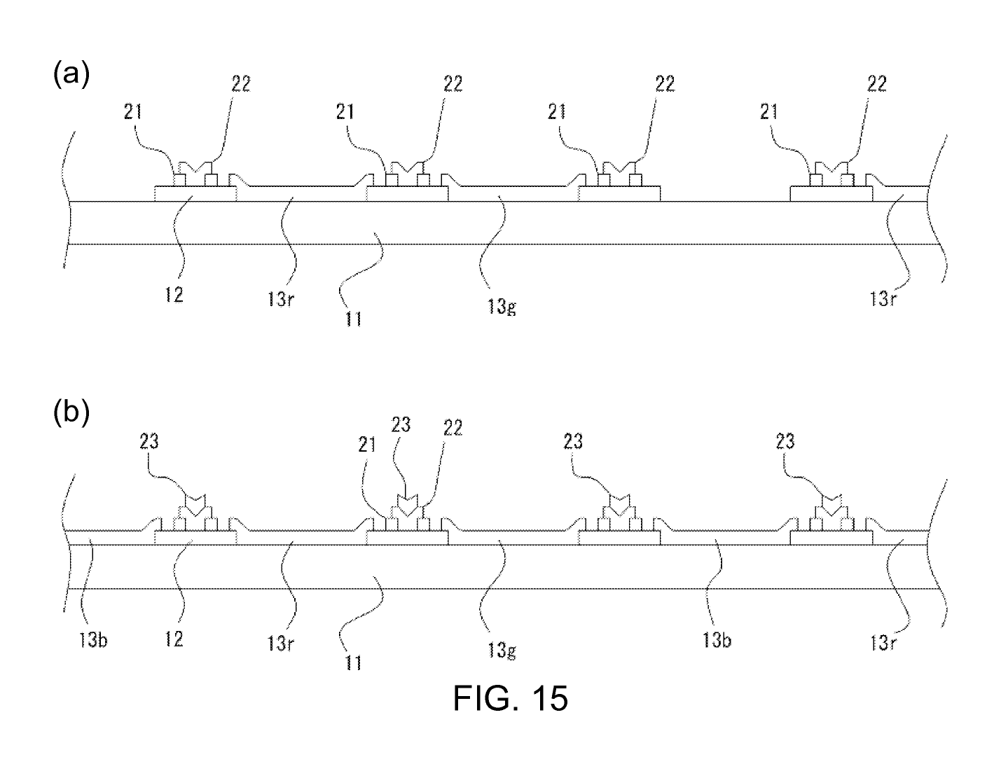

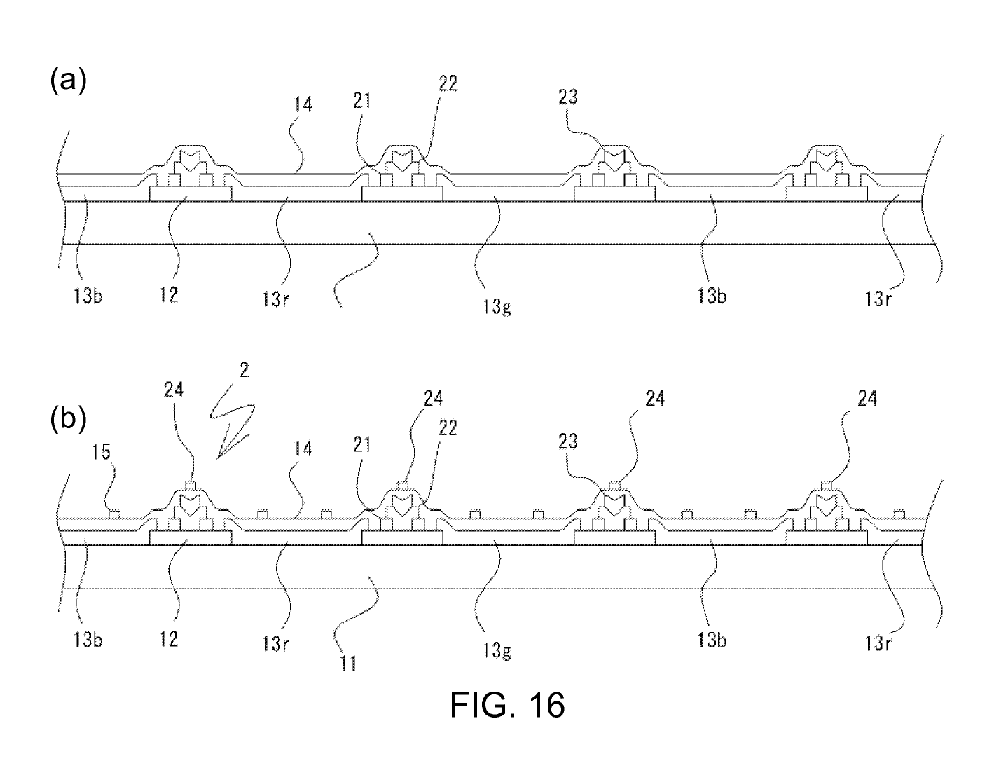

The method of manufacturing the display panel substrate 1 of the embodiment of the present invention will be explained next. The method of manufacturing the display panel substrate 1 of the embodiment of the present invention includes steps of: forming the black matrix, forming the colored pattern, forming the common electrode, and forming the alignment control structures. FIGS. 14, 15, and 16 are cross-sectional drawings that show schematically prescribed steps of the method of manufacturing the display panel substrate 1 of the embodiment of the present invention. Specifically, FIG. 14(a) shows the black matrix formation step, and FIG. 14(b) shows the step of forming a colored pattern of a certain color and the first subspacer of the spacer of the embodiment of the present invention. FIG. 15(a) shows the step of forming a colored pattern of another color and the second subspacer of the spacer of the embodiment of the present invention, and FIG. 15(b) shows the step of forming a colored pattern of yet another color the third subspacer of the spacer of the embodiment of the present invention. FIG. 16(a) shows the step of forming the common electrode, and FIG. 16(b) shows the step of forming the alignment control structures and the fourth subspacer of the spacer of the embodiment of the present invention. These drawings are schematic drawings used for explanations, and the cross-sections are not taken along actual specific cross-section lines.

As shown in FIG. 14(a), the black matrix 12 is formed on the surface of the transparent substrate 11 made of glass or the like. Various types of known methods can be used as the method of forming the black matrix 12. A method of bonding a film made of a photosensitive resin material including a black coloring agent to the surface of the transparent substrate, and patterning the bonded film by the photolithography can be employed, for example. Alternatively, the resin BM method or the like may be utilized. With this process, the substantially lattice-shaped black matrix 12 is formed in the display region 101 of the transparent substrate 11, and a light-shielding film made of a film or a BM resist is formed in a prescribed portion of the panel frame region 102.

The red colored pattern 13r, green colored pattern 13g, and the blue colored pattern 13b for the color display are respectively formed during the colored pattern formation process. During the colored pattern formation process, the first subspacer 21, the second subspacer 22, and the third subspacer 23 of the spacer 2 of the embodiment of the present invention are formed.

Specifically, the forming steps are performed as follows. First, on the surface of the transparent substrate where the black matrix 12 is formed, a photosensitive material film, which is a material of one of the red colored pattern 13r, the green colored pattern 13g, and the blue colored pattern 13b, and a material of the first subspacer 21, is formed. Thereafter, the formed photosensitive material film is patterned by the photolithography method. The photomask used during the exposure step of this photolithography method has a light-transmitting pattern and a light-shielding pattern for forming the first subspacer 21, and has a light-transmitting pattern and a light-shielding pattern for forming one of the colored patterns 13r, 13g, and 13b. That is to say, if the film is made of the positive type photosensitive material, the first photomask 9a is used, and if the film is made of the negative type photosensitive material, the second photomask 9b is used.

With this patterning, the colored pattern of a certain color 13r, 13g, or 13b is formed in a prescribed pixel (the drawing shows a configuration where the red colored pattern 13r is formed). Simultaneously, the first subspacer 21 of the spacer 2 of the embodiment of the present invention is formed at a prescribed position of the surface of the black matrix 12. In this manner, the first subspacer 21 is formed of the same photosensitive material as that of one of the colored patterns 13r, 13g, and 13b (the red colored pattern 13r in the drawing). The dimensions of the opening 211 formed in the first subspacer 21 are adjusted by making an adjustment to at least one of the light energy intensity and the light energy irradiation time during exposure process of the photosensitive material film. Even if the light energy intensity and/or light energy irradiation time are changed, the thickness of the photosensitive material film (thickness of the colored pattern 13r, 13g, or 13b) remaining after development treatment does not change. Thus, it is possible to adjust dimensions of the opening 211 of the first subspacer 21 (i.e., the overall height H of the spacer 2 of the embodiment of the present invention) without affecting the color characteristics of the colored patterns 13r, 13g, and 13b.

When the positive type photosensitive material is used, if the radiated light energy intensity becomes stronger, or if the light energy irradiation time becomes longer (or if the irradiated light energy intensity is decreased and the light energy irradiation time becomes longer at the same time), dimensions of the outer shape of the formed colored pattern 13r, 13g, or 13b decrease. However, if the peripheral edge portion of the colored pattern 13r, 13g, or 13b is made to overlap the black matrix 12, and if margin of the overlapping dimension is set so as to make allowance for the decrease in dimensions, it becomes possible to form the colored pattern 13r, 13g, or 13b over the entire opening of each pixel. Thus the color characteristics of each pixel are not affected.

Next, as shown in FIG. 15(a), the second subspacer 22 of the spacer 2 of the embodiment of the present invention is formed, and a colored pattern 13r, 13g, or 13b of a color different from that of the colored pattern 13r, 13g, or 13b formed in the above-mentioned process. In this drawing, a configuration where the second subspacer 22 of the spacer 2 of the embodiment of the present invention and the green colored pattern 13g are formed of the same photosensitive material and in the same process is shown. As described above, the second subspacer 22 and a colored pattern 13r, 13g, or 13b of a certain color are formed of the same photosensitive material. However, the second subspacer 22 is formed of a photosensitive material that is the same as that a colored pattern 13r, 13g, or 13b of a color different from that of the first subspacer 21.

As shown in FIG. 15(b), the third subspacer 23 of the spacer 2 of the embodiment of the present invention is formed, and a colored pattern 13r, 13g, or 13b of a color different from the colored patterns 13r, 13g, or 13b formed in the aforementioned process is formed. FIG. 15(b) shows a process of forming the third subspacer 23 of the spacer 2 of the embodiment of the present invention and the blue colored pattern 13b of the same photosensitive material in the same process. As described above, the third subspacer 23 and a colored pattern 13r, 13g, or 13b of a certain color are formed of the same photosensitive material. However, the third subspacer 22 is formed of the same photosensitive material as that of the colored pattern 13r, 13g, or 13b of a color different from those of the first subspacer 21 and the second subspacer 22. That is to say, the first subspacer 21, the second subspacer 22, and the third subspacer 23 are formed of the same photosensitive material as those of the colored patterns 13r, 13g, and 13b of the colors that are different from one another, respectively.

The colored patterns 13r, 13g, and 13b of the respective colors, the second subspacer 22, and the third subspacer 23 can be formed by the typical photolithography method. The photomask used in the photolithography has a light-transmitting pattern and a light-shielding pattern for forming the colored pattern 13r, 13g, or 13b of the respective color, a light-shielding pattern and a light-transmitting pattern for forming the second subspacer or a light-shielding pattern and a light-transmitting pattern for forming the third subspacer. With this configuration, it becomes possible to form the second subspacer 22 and the third subspacer 23 simultaneously with the respective colored pattern 13r, 13g, or 13b in the steps of forming the colored patterns 13r, 13g, or 13b of the respective colors.

Thereafter, as shown in FIG. 16(a), in the step of forming the common electrode 14, the common electrode 14 is formed on the surfaces of the black matrix 12 and the colored patterns 13r, 13g, and 13b. Various types of known methods may be used for forming the common electrode 14, such as the masking method, the photolithography method, or the like.

If the masking method is used, for example, a mask having an opening of a prescribed pattern (opening of the pattern of the common electrode 14, for example) is placed on the surface of the transparent substrate 11 that has undergone the aforementioned step, and a sputtering or the like is performed so as to deposit a transparent conductive material on the surface of the transparent substrate that has undergone the aforementioned step through the opening formed in the mask, thereby forming the common electrode 14 of the prescribed pattern on the surface of the transparent substrate that has undergone the aforementioned step. Alternatively, when the photolithography method is used, a film of transparent conductive material is formed on the surface of the substrate 11 that has undergone the aforementioned process, and the formed conductive material film is patterned into the pattern on the common electrode 14 by etching. Wet etching using ferric chloride may be utilized for this etching. As the transparent conductive material, ITO (indium tin oxide) can be used.

Thereafter, as shown in FIG. 16(b), the alignment control structure 15 and the fourth subspacer 24 of the spacer 2 of the embodiment of the present invention are formed. The alignment control structure 15 and the fourth subspacer 24 are formed of the same photosensitive material in the same step. A conventional known photolithography method can be used as the method of forming the alignment control structure member 15 and the fourth subspacer 24. That is to say, they can be formed by a method of forming a photosensitive material film, which is the material of the alignment control structure 15 and the fourth subspacer 24, on the surface of the common electrode 14, performing exposure to the formed photosensitive resin material film using a photomask having a light-transmitting pattern and a light-shielding pattern for forming the alignment control structure 15 and the fourth subspacer 24, and thereafter performing a development process. Thus, the detailed explanation thereof is omitted.

The display panel substrate 1 of the embodiment of the present invention is manufactured through the aforementioned steps.

By using the display panel substrate 1 of the embodiment of the present invention, it becomes possible to obtain the operational effects that were described as the operational effects of the spacer 2 of the embodiment of the present invention. Further, the following operational effects can be realized.

The display panel substrate 1 of the embodiments of the present invention differs from a configuration where the height dimension of the spacer 2 is adjusted through the adjustment of the thickness of the black matrix 12 in that the thickness of the black matrix 12 does not affect the overall height of the spacer 2 of the embodiments of the present invention. That is to say, there is no need to adjust the height of the black matrix 12 so as to adjust the overall height of the spacer 2 of the embodiments of the present invention. Therefore, it is possible to employ, as the method for forming the black matrix 12, a method that does not allow for the thickness adjustment of the black matrix 12 or a method that makes is difficult to adjust the thickness.

It is possible to use, as the method for formation of the black matrix 12, a method of bonding (or laminating) a film including a black coloring agent to a transparent substrate, and patterning the bonded film so as to form the black matrix 12, for example. This method does not allow the thickness to be adjusted because the thickness of the bonded film (or laminated film) determines the thickness of the black matrix 12.

In this manner, because there is no need to change the thickness of the black matrix 12 during the process of forming the black matrix 12, it is possible to employ a method that does not allow for the thickness adjustment of the black matrix 12 as described above. This increases the number of alternative methods that can be used to form the black matrix 12.

### INDUSTRIAL APPLICABILITY

Although the embodiments of the present invention have been explained in detail above with reference to drawings, the present invention is not limited to the aforementioned embodiments, and it is apparent that various modifications can be made without departing from the scope of the present invention.

In the aforementioned embodiments, a configuration with four layers of subspacers has been described as an example. However, there is no limitation on the number of subspacers. That is to say, a configuration with two layers of subspacers, or three layers of subspacers, or a configuration with five or more layers of subspacers may be employed. In summary, any configuration may be used as long as there is at least a subspacer having an opening and another subspacer overlapping the subspacer that has the opening.

In the aforementioned embodiments, a configuration where the display panel substrate has colored patterns of three colors has been described. However, there is no limitation on the number of colors of the colored patterns. The colored patterns may also be configured to have five colors, for example. The subspacer having the opening needs to be configured such that it is formed of the same material as that of the colored pattern of a single color among those colors.

1. A spacer formed by laminating a plurality of subspacers, comprising:
a first subspacer that has an opening in a center portion thereof in a plan view; and
a second subspacer that has a portion thereof partially overlapping said first subspacer and that has another portion thereof engaging said opening in said first subspacer.

2. The spacer according to claim 1, wherein said first subspacer is formed of a photosensitive material.

3. A display panel substrate that includes a spacer, the spacer comprising:
a first subspacer that has an opening in a center portion thereof in a plan view; and
a second subspacer that has a portion thereof partially overlapping said first subspacer and that has another portion thereof engaging said opening formed in said first subspacer.

4. The display panel substrate according to claim 3, wherein said first subspacer is formed of a photosensitive material.

5. A display panel substrate, comprising:
colored patterns of a prescribed plurality of colors for a color display, the colored patterns being formed of photosensitive materials; and
a spacer that comprises a first subspacer and a second subspacer, the first subspacer having an opening in a center portion thereof in a plan view, the second subspacer having a portion thereof partially overlapping said first subspacer and having another portion thereof engaging said opening in said first subspacer,
wherein said first subspacer is formed of a same material as a colored pattern of one color among the colored patterns of the plurality of colors.

6. The display panel substrate according to claim 5, wherein said second subspacer is formed of a same material as a colored pattern of a color that is different from that of the first subspacer.

7. A method for forming a spacer, comprising:
forming a first subspacer having an opening in a center portion thereof in a plan view; and
forming a second subspacer that is laminated such that a portion thereof engages said opening in said first subspacer,
wherein, during the step of forming the first subspacer having the opening in the center portion thereof in a plan view, a height of a top surface of said second subspacer is adjusted by adjusting dimensions of the opening in said first subspacer so as to adjust a volume of the portion of said second subspacer engaging said opening.

8. The method for forming a spacer according to claim 7, wherein said step of forming the first subspacer having the opening in the center portion thereof in a plan view includes:
forming a photosensitive material film;
exposing said photosensitive material film by radiating light energy to said photosensitive material film through a photomask that has a light-transmitting pattern and a light-shielding pattern, the light-transmitting pattern corresponding to said first subspacer, the light-shielding pattern corresponding to said opening in said first subspacer; and
developing the photosensitive film that has undergone the exposure,
wherein, during said exposure, dimensions of said opening in said first subspacer are adjusted by adjusting an amount of light energy radiated to a portion of said photosensitive material film where said light-shielding pattern of said photomask is projected.

9. The method for forming a spacer according to claim 7, wherein said step of forming the first subspacer having the opening in the center portion thereof in a plan view includes:
forming a positive type photosensitive material film;
exposing said photosensitive material film by radiating light energy to said photosensitive material film through a photomask that has a light-transmitting pattern and a light-shielding pattern, the light-transmitting pattern corresponding to said opening in said first subspacer, the light-shielding pattern corresponding to said first subspacer; and
developing said photosensitive film that has undergone the exposure,
wherein, during said exposure step, dimensions of said opening in said first subspacer are adjusted by adjusting an amount of light energy radiated to a portion of said positive type photosensitive material film where said light-shielding pattern of said photomask is projected and therefore by adjusting a region of said photosensitive material film to be removed during said development step.

10. The method for forming a spacer according to claim 7, wherein said step of forming the first subspacer having the opening in the center portion thereof in a plan view includes:
forming a negative type photosensitive material film;
exposing said photosensitive material film by radiating light energy to said photosensitive material film through a photomask that has a light-transmitting pattern and a light-shielding pattern, the light-transmitting pattern corresponding to said first subspacer, the light-shielding pattern corresponding to said opening in said first subspacer; and
developing said photosensitive film that has undergone the exposure,
wherein, during said exposure step, dimensions of said opening in said first subspacer are adjusted by adjusting an amount of light energy radiated to a portion of said negative type photosensitive material film where said light-shielding pattern of said photomask is projected, and by therefore adjusting a region of said photosensitive material film that remains after said development step.

11. A method for manufacturing a substrate for a display panel that has colored patterns of a prescribed plurality of colors, the method comprising:
forming a first subspacer that has an opening in a center portion thereof in plan view simultaneously with a colored pattern of one color among the prescribed plurality of colors; and
forming a second subspacer, which is being laminated such that a portion thereof engages said opening in said first subspacer, simultaneously with a colored pattern of another color among the prescribed plurality of colors,
wherein, during said step of forming said first subspacer having said opening in the center portion thereof in the plane direction, a height of a top surface of said second subspacer is adjusted by adjusting dimensions of said opening in said first subspacer, and by therefore adjusting a volume of the portion of said second subspacer engaging said opening.

12. The method for manufacturing a substrate for a display panel according to claim 11, wherein said step of forming the first subspacer that has the opening in the center portion thereof in a plan view simultaneously with the colored pattern of one color among the prescribed plurality of colors includes:
forming a photosensitive material film;
exposing said photosensitive material film by radiating light energy to said photosensitive material film through a photomask that has a light-shielding pattern and a light-transmitting pattern, the light-shielding pattern corresponding to said colored pattern of one color and said first subspacer, the light-transmitting pattern corresponding to said opening to be formed in said first subspacer; and
developing said photosensitive film that has undergone the exposure,
wherein, during said exposure step, said colored pattern of one color is formed, and dimensions of said opening in said first subspacer are adjusted by adjusting an amount of light energy radiated to a portion of said photosensitive material film where said light-shielding pattern of said photomask is projected.

13. The method for manufacturing a substrate for a display panel according to claim 11, wherein said step of forming the first subspacer having the opening in the center portion thereof in a plan view simultaneously with the colored pattern of one color among the prescribed plurality of colors includes:
forming a positive type photosensitive material film;
exposing said photosensitive material film by radiating light energy to said photosensitive material film through a photomask that has a light-shielding pattern corresponding to said colored pattern of one color, a light-shielding pattern corresponding to said first subspacer, and a light-transmitting pattern corresponding to said opening to be formed in said first subspacer; and
developing said positive type photosensitive film that has undergone the exposure,
wherein, during said exposure step, said colored pattern of one color is formed, and dimensions of said opening in said first subspacer are adjusted by adjusting an amount of light energy radiated to a portion of said positive type photosensitive material film where said light-shielding pattern of said photomask is projected, and by therefore adjusting a region of said photosensitive material film to be removed during said development step.

14. The method for manufacturing a substrate for a display panel according to claim 11, wherein said step of forming the first subspacer that has the opening in the center portion thereof in a plan view simultaneously with the colored pattern of one color among the prescribed plurality of colors includes:
forming a negative type photosensitive material film;
exposing said negative type photosensitive material film by radiating light energy to said photosensitive material film through a photomask that has a light-transmitting pattern corresponding to said colored pattern of one color, a light-transmitting pattern corresponding to said first subspacer, and a light-shielding pattern corresponding to said opening to be formed in said first subspacer; and
developing said negative type photosensitive film that has undergone the exposure,
wherein, during said exposure step, said colored pattern of one color is formed, and dimensions of said opening in said first subspacer are adjusted by adjusting an amount of light energy radiated to a portion of said positive type photosensitive material film where said light-shielding pattern of said photomask is projected, and by therefore adjusting a region of said photosensitive material film to be remained after said development step.
